(19) United States
(12) Patent Application Publication
(10) Pub. No.: US 2026/0248037 A1
(43) Pub. Date: Aug. 20, 2026

(54) INTERPOSER FOR BRIDGING CHIPS

(71) Applicant: CIENA CORPORATION, Hanover, MD (US)

(72) Inventors: Raphaël Beaupré-Laflamme, Québec (CA); Lam Nguyen, Quebec city (CA)

(73) Assignee: CIENA CORPORATION, Hanover, MD (US)

(21) Appl. No.: 19/056,906

(22) Filed: Feb. 19, 2025

(51) Int. Cl. H01L 25/16; G02B 6/42; H01L 23/00; H01L 23/538; H01L 25/00

(52) U.S. Cl. CPC H10W 90/00; G02B 6/4284; H10W 70/611; H10W 70/614; H10W 70/635; H10W 90/722; H10W 90/724; H10W 90/755

(57) ABSTRACT

Aspects of the subject disclosure may include, for example, a device including a body having a cavity defined therein for hosting a first IC, the body further having a portion adjacent to the cavity, the portion having a supporting surface for supporting and providing electrical interconnection to a second IC, wherein the device facilitates bridging of the second IC at least partially over the first IC when the first IC is disposed in the cavity and the second IC is disposed over the supporting surface. Other embodiments are disclosed.

### FIELD OF THE DISCLOSURE

The subject disclosure relates to methods and devices for facilitating bridging of one chip, such as an electronic integrated circuit (EIC), over an interposer-mounted chip, such as a photonic integrated circuit (PIC).

### BACKGROUND

Many optical communication systems include integrated circuits (ICs), such as PICs and EICs. A PIC includes one or more optical sources (e.g., lasers), modulators, and detectors that generate, modulate, and detect optical signals. An EIC includes electronic circuitry that is configured to drive the PIC and process electrical signals. These two chips need to be electrically connected to one another in order for the optical communication system to function.

Fan-Out Wafer Level Packaging (FOWLP) is a packaging technology in which radio frequency (RF) interconnects are formed between chips by embedding the chips in a molding compound and creating fan-in/fan-out interconnects using redistribution layers (RDL). This is mainly done as a back end of line (BEOL) process at the wafer level. FOWLP can also be used in other applications not involving RF. In any case, FOWLP has several disadvantages when it comes to integrating PICs and EICs in higher performance optical communication systems. First, it is difficult to integrate the PIC since the facet of the PIC needs to be clean, which is hazardous when the whole chip is epoxy molded. Additionally, the FOWLP assembly process (and even the assembly process of other faster techniques) is sequential to PIC fabrication, meaning that the entire process flow requires that the PIC be first built and ready, which adds PIC fabrication lead time to the overall packaging lead time. Further, the use of RDLs on a top surface of the PIC adds excessive capacitive loss on the high-speed RF interconnect.

Three-dimensional (3D) packaging using through-silicon vias (TSVs) is a packaging technique that involves vertically stacking multiple chips over one another, and establishing electrical connections between them by way of vertical vias that pass through the silicon of the host chip. This approach also has several disadvantages. First, it requires the PIC to be thinned down to 100-200 micrometers (μm), which makes it highly fragile and incompatible with current state-of-the-art (SOA) integration techniques. Additionally, TSV-first processes, where the TSVs are built at the complementary metal-oxide-semiconductor (CMOS) fab, are not readily available in many fabrication facilities. Further, TSV-last processes, where the TSVs are added to the completed wafer, have higher wafer-related costs as well as longer lead times (e.g., six months or more).

Other techniques for interconnecting the chips involve the use of RF wire bonds. However, wire bonds introduce excess loss, especially at high frequencies, and also increase the distance between the chips.

### BRIEF DESCRIPTION OF THE DRAWINGS

Reference will now be made to the accompanying drawings, which are not necessarily drawn to scale, and wherein:

FIG. 1A is a perspective view of an example assembly in which a carrier-interposer facilitates bridging of an EIC over a PIC.

FIG. 1B is a top down view of the assembly of FIG. 1A.

FIG. 1C shows a side view and a cross-sectional side view of the assembly of FIG. 1A.

FIG. 1D is a perspective view of the carrier-interposer of FIG. 1A.

FIG. 1E is a top down view of the carrier-interposer of FIG. 1A.

FIG. 1F shows a side view and a cross-sectional side view of the carrier-interposer of FIG. 1A.

FIG. 1G is a perspective view of the carrier-interposer and the PIC of FIG. 1A.

FIG. 1H shows an example assembly in which a carrier-interposer is configured to host a single PIC and multiple EICs that bridge over the PIC.

FIG. 1I shows an example assembly in which a carrier-interposer is configured to host multiple PICs and a single EIC that bridges over the multiple PICs.

FIG. 1J shows an example assembly in which a carrier-interposer is configured to host multiple PICs and multiple EICs that respectively bridge over corresponding ones of the PICs.

FIG. 1K shows a cross-sectional side view of an example version of the assembly of FIG. 1A including an additional balancing shim and an additional adhesive layer/bond in a cavity of the carrier-interposer.

FIG. 1L is a perspective view of an example assembly in which a composite carrier-interposer, including first and second stage interposers, facilitates bridging of an EIC over a PIC.

FIG. 1M shows a side view and a cross-sectional side view of the assembly of FIG. 1L.

FIG. 2 depicts an illustrative embodiment of a method in accordance with various aspects described herein.

### DETAILED DESCRIPTION

The subject disclosure describes, among other things, illustrative embodiments of a carrier-interposer for facilitating bridging of a first IC over a second IC. The carrier-interposer may include a body that is defined with a cavity for hosting, or having embedded or installed therein, the first IC. The body may include a portion that is adjacent to the cavity for supporting the second IC. Where this second IC is an active chip, for instance, the second IC can be flip-chip attached to the first IC and the portion of the carrier-interposer body.

The carrier-interposer may include sets of electrically-conductive vias for coupling electrical contacts (or a contact pad array) that are disposed on a first (e.g., top side) of the carrier-interposer with electrical contacts (pillars or bumps) that are disposed on a second (e.g., bottom side) of the carrier-interposer. The carrier-interposer may include respective ones of these sets for facilitating electrical interconnections with respective electrical contacts (or contact pad arrays) of the first IC and the second IC. In one or more embodiments, a first contact pad array of the carrier-interposer and a first electrical contacts of the first IC may be arranged relative to one another such that, when the first IC is installed in the cavity, a second contact pad array of the carrier-interposer and second electrical contacts of the first IC are aligned to form a (e.g., complete) contact pad pattern for flip-chip attachment of the second IC.

An example process for assembling the carrier-interposer with the first and second ICs may include dispensing or applying an adhesive layer on a (e.g., lower) surface of the cavity, aligning the first IC (e.g., in all axes) relative to a contact pad array pattern of the carrier-interposer, curing the adhesive layer, flip-chip attaching the second IC (or bridging chip), and dispensing or applying an underfill beneath the second IC and curing that underfill. In one or more embodiments, the adhesive layer may be configured to facilitate balanced (or near balanced) thermal expansion between the first IC and the carrier-interposer. In certain embodiments, one or more balancing shims may additionally, or alternatively, be included in the cavity between the first IC and the carrier-interposer to facilitate balanced (or near balanced) thermal expansion in the stack-up.

In various embodiments, the cavity may be configured to accommodate multiple first ICs and/or the portion of the body adjacent to the cavity may be configured to accommodate multiple second ICs. Where the first IC is a PIC, an optical facet thereof may be left exposed by a notch or an opening in the cavity, to allow for edge coupling. Permitting embedding of multiple PICs, such as different semiconductors, different chiplets, etc., allows for increased PIC yield.

Exemplary embodiments of interposer-based chip bridging advantageously enable simpler integration of the PIC since the PIC can be coupled (or attached) to the carrier-interposer with (e.g., only) a bottom-side bond line of adhesive, which allows for a clean optical facet. The carrier-interposer can be fabricated in advance of PIC reception, which reduces the remaining assembly time. The thickness of the PIC can also be kept above 300-400 μm, if needed, allowing it to remain sturdy. If there is a desire to thin down the PIC, the rigid carrier-interposer would protect the chip during later integration processes as well as from eventual board/substrate stresses.

Facilitating bridging of chips also reduces or eliminates the need for RF wire bonds between the chips, which reduces RF signal-related losses. RF signal paths that are composed of transitions and transmission lines have been shown to induce low loss even at high frequencies, which allows for increased bandwidth (>120 Gigahertz (GHz)) that is generally difficult to reach with mere wire bonds. Of course, wire bonds can nevertheless be used between the PIC and the carrier-interposer for DC signals if desired, given their relatively lower cost and high reliability. Direct mounting of the EIC to the PIC (e.g., through copper pillars, chip connection (C2) bumps, controlled collapse chip connection (C4) bumps, or the like) also generally reduces signal loss where signal integrity (e.g., RF connections) is critical.

Employing the carrier-interposer for hosting a PIC, as described herein, also advantageously exposes a majority of a (e.g., upper) surface of the PIC to air or the atmosphere, rather than to another type of material, such as a dielectric material, which helps reduce potential interference or attenuation that might otherwise result from the use of such other material. Exposing the PIC to air or the atmosphere can also aid in thermal management, as it allows for better heat dissipation (e.g., warm areas can be exposed to an eventual heat sink), thereby enhancing the overall reliability and performance of the optical communication system. Furthermore, exposing the PIC also allows for the integration or use of other PIC technologies, such as III-V lasers, amplifiers, etc. in silicon photonics.

Exemplary embodiments of interposer-based chip bridging also allow for high-volume, compatible wafer-level packaging (e.g., in cases where the carrier-interposer is composed of glass or is ceramic-based) or panel-level packaging (e.g., in cases where it is substrate-based, glass-based, and/or ceramic-based). Indeed, most of the assembly process can be performed at the wafer-level or panel-level, if needed. For instance, carrier-interposers may be positioned on their respective panels and populated with respective PICs and EICs before being singulated and assembled in individual products. The advantageous architecture also reduces or eliminates a need for a product developer to rely on third-party, Outsourced Semiconductor Assembly and Test (OSAT) integrators for chip assembly, which allows for increased customization as well as reduced production lead times and lower costs.

One or more aspects of the subject disclosure include a device. The device may include a body having a cavity defined therein for hosting a first integrated circuit (IC), the body further having a portion adjacent to the cavity, the portion having a supporting surface for supporting and providing electrical interconnection to a second IC, wherein the device facilitates bridging of the second IC at least partially over the first IC when the first IC is disposed in the cavity and the second IC is disposed over the supporting surface.

One or more aspects of the subject disclosure include an apparatus. The apparatus may include one or more first integrated circuits (ICs), one or more second ICs, and a carrier-interposer having a body that is defined with a cavity, the one or more first ICs being disposed in the cavity, the body further having a portion adjacent to the cavity, the portion having a supporting surface, and the one or more second ICs being disposed over the supporting surface, wherein the one or more second ICs are bridged at least partially over the one or more first ICs and electrically interconnected to the one or more first ICs.

One or more aspects of the subject disclosure include a method. The method may include disposing a first integrated circuit (IC) in a cavity that is defined in a body of a carrier-interposer, wherein the disposing results in a gap between the first IC and a portion of the body, and positioning a second IC onto a supporting surface of the portion of the body, wherein the positioning results in the second IC at least partially bridging the gap.

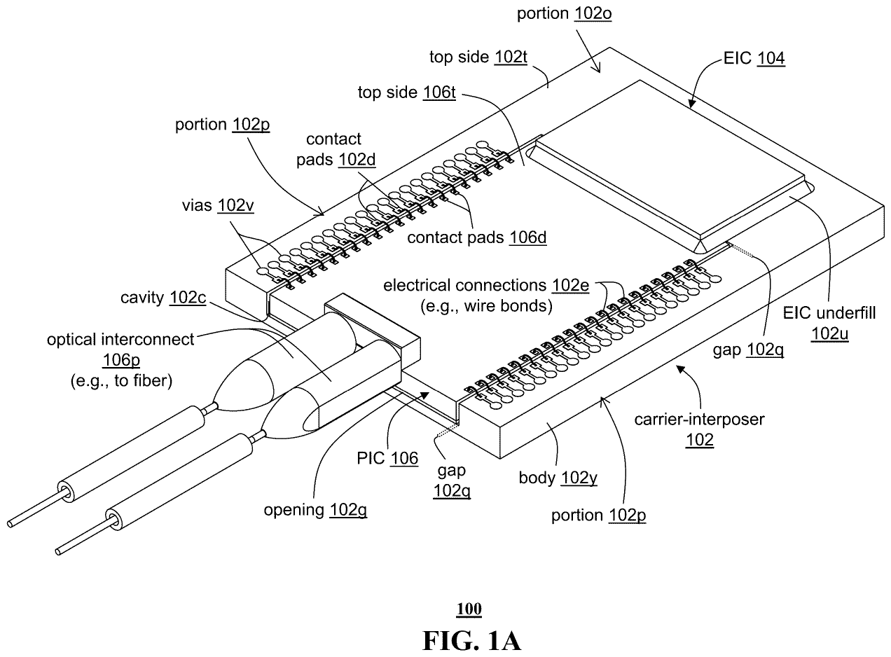

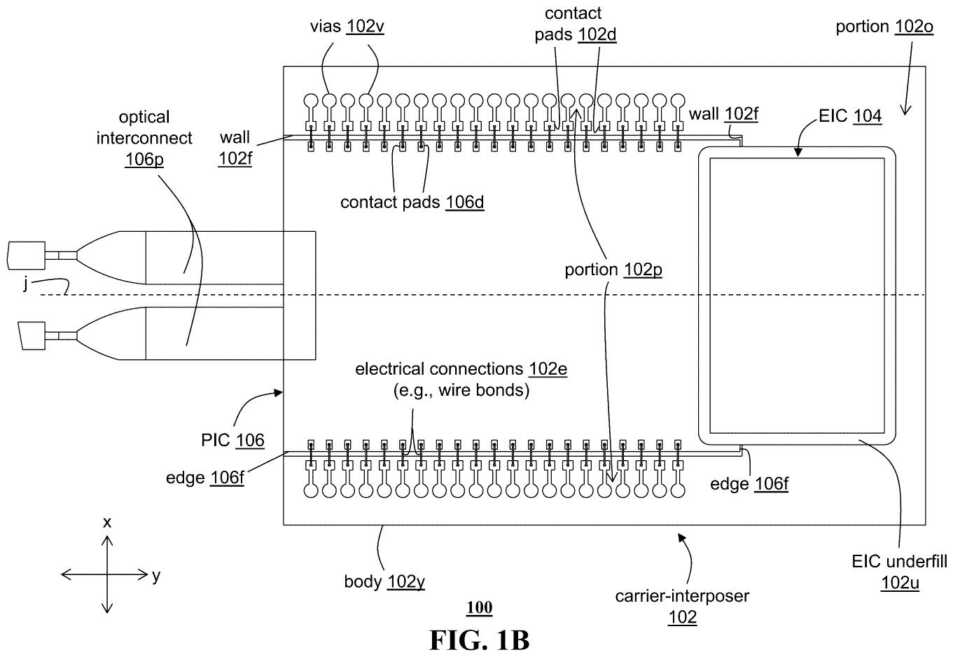

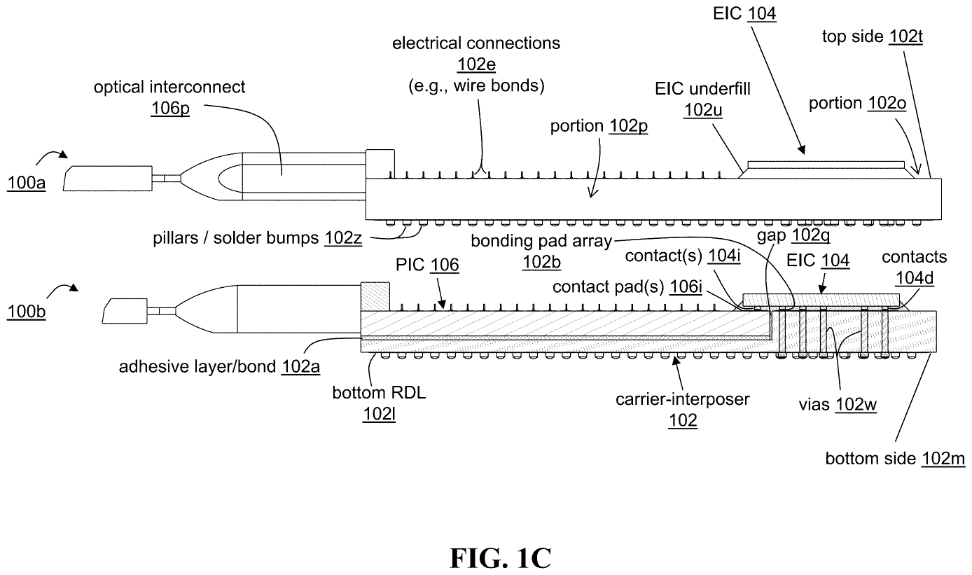

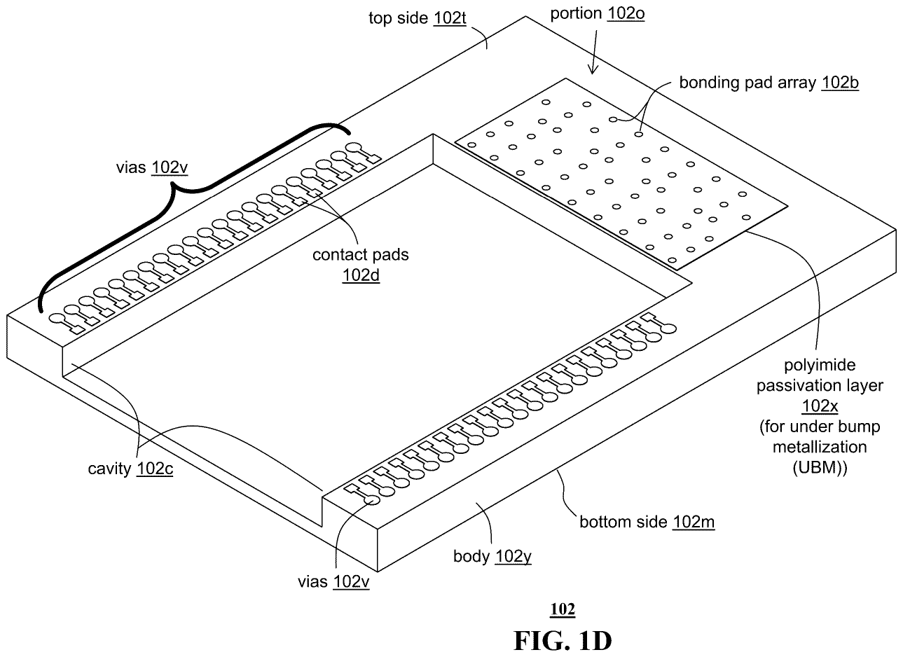

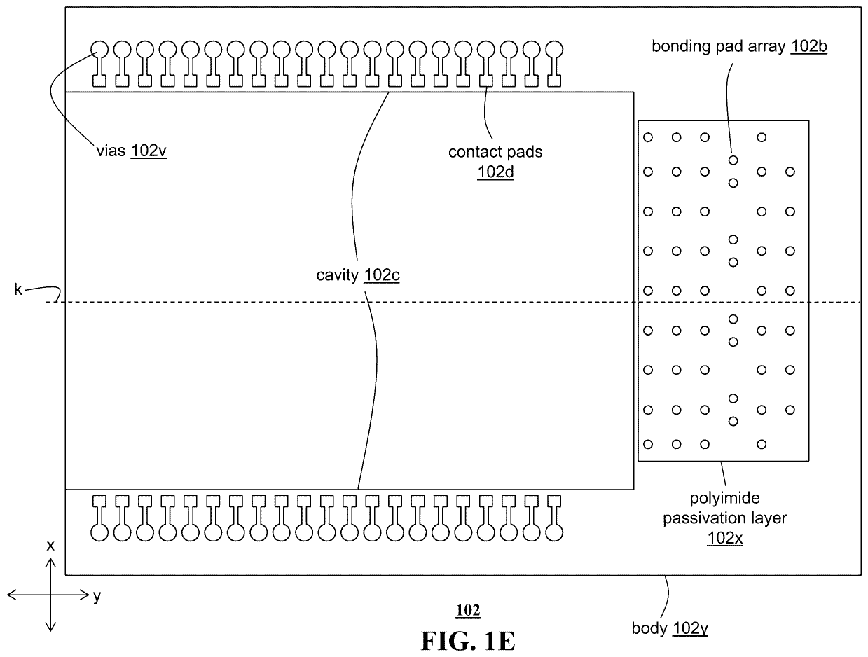

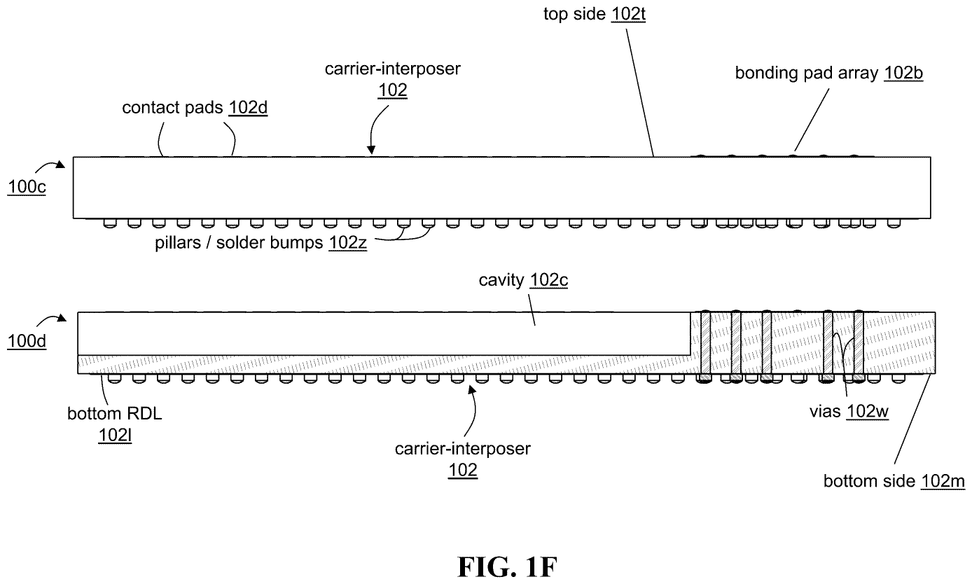

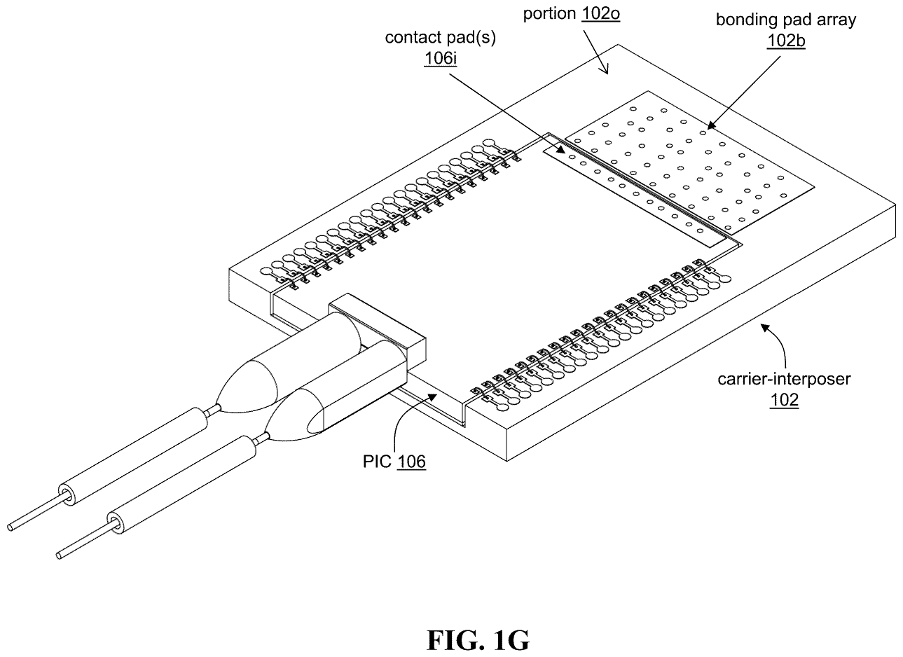

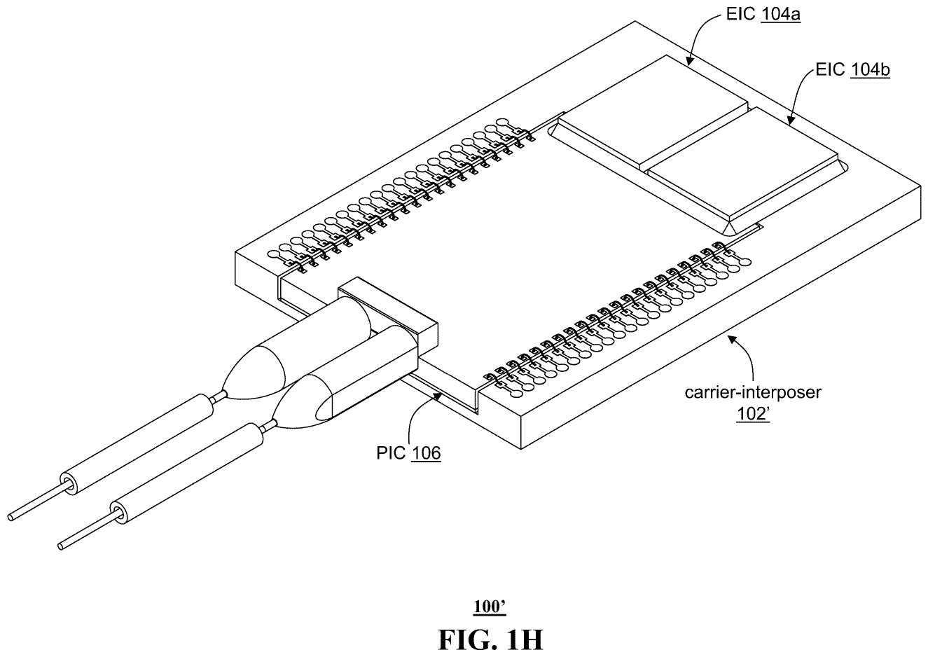

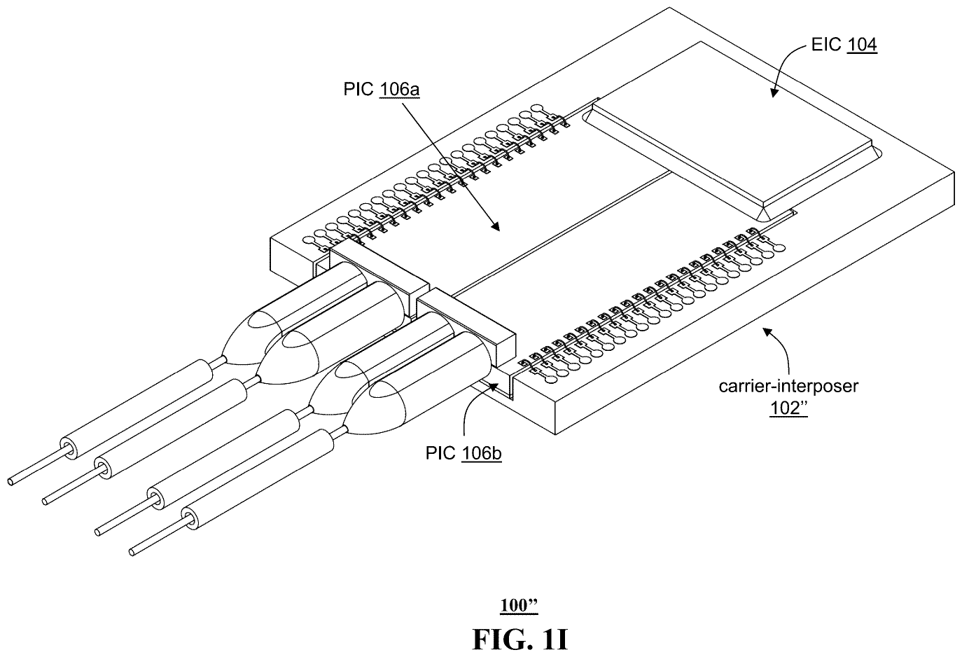

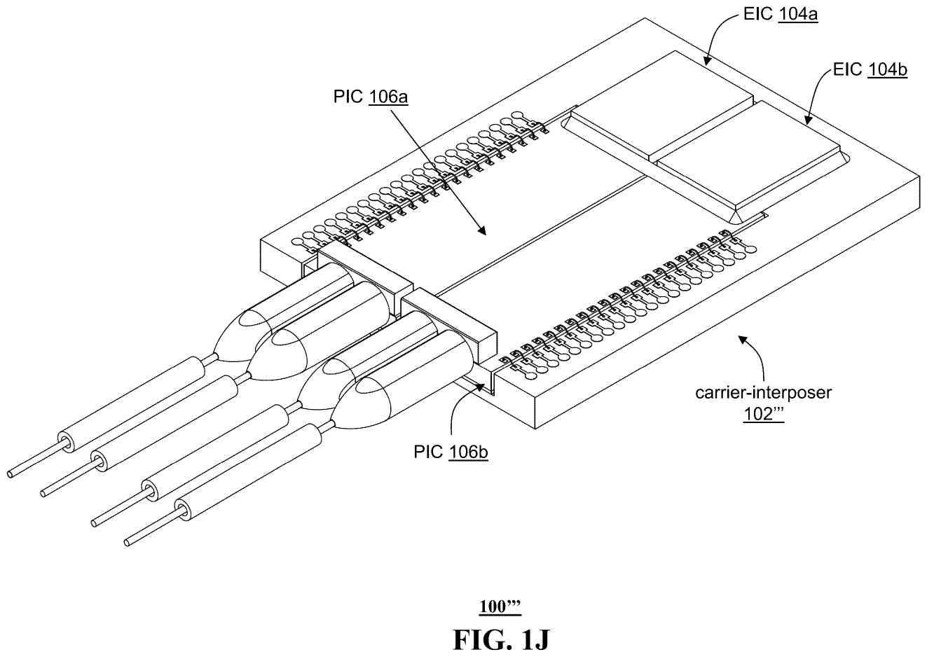

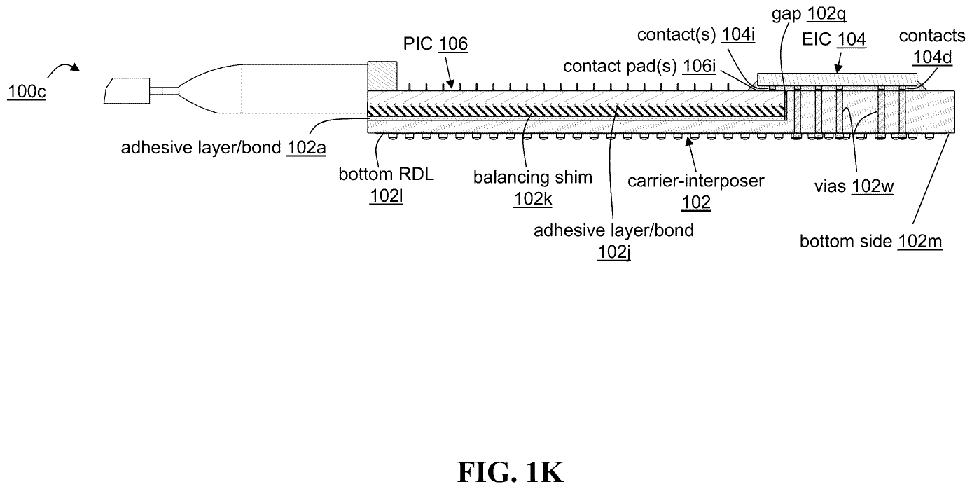

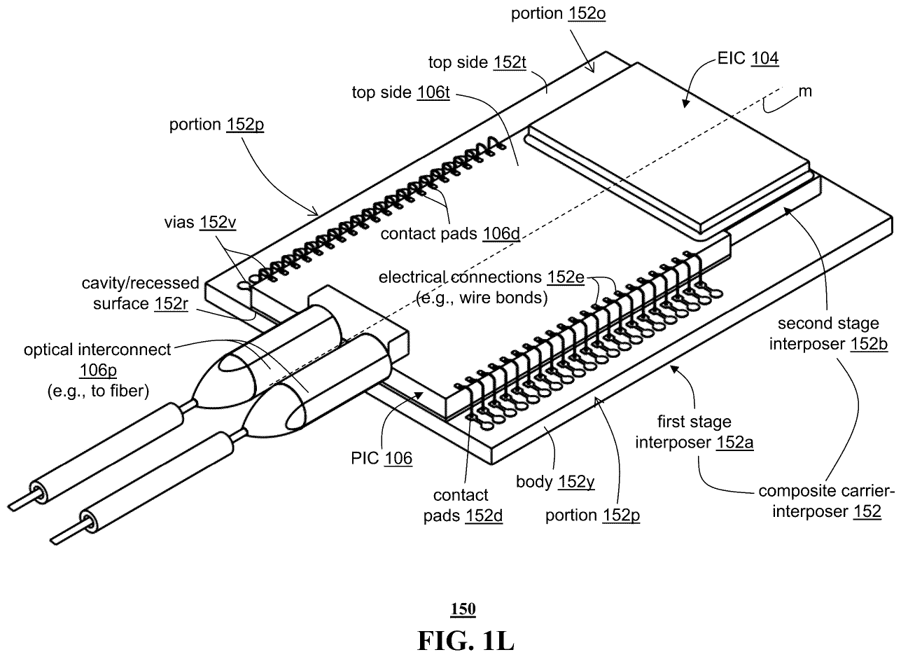

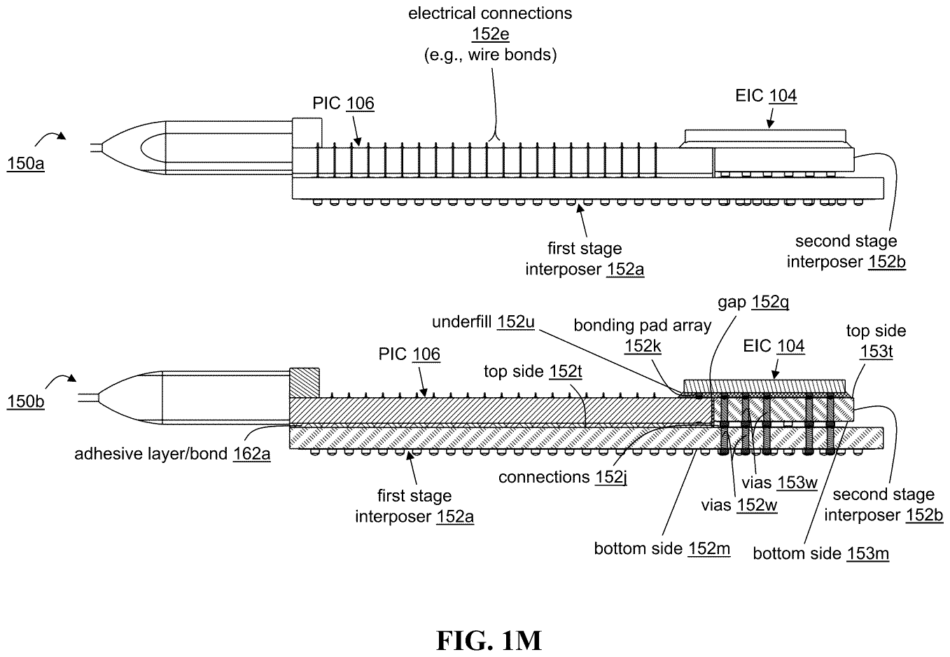

FIG. 1A is a perspective view of an example assembly 100 in which a carrier-interposer 102 facilitates bridging of an EIC 104 over a PIC 106. FIG. 1B is a top down view of the assembly 100 of FIG. 1A, and FIG. 1C shows a side view 100a and a cross-sectional side view 100b of the assembly 100 of FIG. 1A (e.g., taken along line j or a line parallel thereto in FIG. 1B).

The PIC 106 may be a photonic chip (e.g., silicon photonics (SiPhot)), such as a transmitter electro-optic (E-O) modulator or a receiver opto-electronic (O-E) modulator. The PIC 106 may include devices such as Mach-Zehnder modulator(s), ring modulator(s), photodetector(s), and/or optical source(s) (e.g., lasers). The EIC 104 may be an electronic chip, and may include one or more electronic components, such as driver(s), amplifier(s), and/or signal processor(s) that are configured to interface with and/or control the PIC 106.

The carrier-interposer 102 may include a body 102y having a portion 1020 and a portion 102p. The body 102y may be defined with a cavity 102c that is configured to host or support the PIC 106. FIG. 1D is a perspective view of the carrier-interposer 102, FIG. 1E is a top down view of the carrier-interposer 102, and FIG. 1F shows a side view 100c and a cross-sectional side view 100d of the carrier-interposer 102 (e.g., taken along a line k or a line parallel thereto in FIG. 1E).

The carrier-interposer 102, and more particularly the portion 102p of the body 102y, may be defined with vias 102v (e.g., through carrier vias), that are respectively coupled to or defined in electrical contact pads 102d, for routing electrical signals from a top side (or surface) 102t of the carrier-interposer 102 to a bottom side 102m of the carrier-interposer 102. The electrical contact pads 102d may be arranged to facilitate electrical connections 102e (e.g., wire bonding) with corresponding electrical contact pads 106d of the PIC 106.

The carrier-interposer 102, and more particularly, the portion 1020 of the body 102y may also be defined with vias 102w (e.g., through carrier vias), that are respectively coupled to or defined in bonding pads of a bonding pad array 102b, for routing electrical signals from the top side 102t of the carrier-interposer 102 to the bottom side 102m of the carrier-interposer 102. The bonding pad array 102b may be arranged on the top side 102t of the portion 1020 for facilitating electrical connections with corresponding electrical contacts 104d of the EIC 104. See, e.g., FIGS. 1C and 1D.

The inclusion of vias 102v and/or 102w in the carrier-interposer 102 advantageously reduces or eliminates a need for vias in the PIC 106 or the EIC 104, and thus no modifications to the structures of the PIC 106 and/or the EIC 104 may be needed.

In some embodiments, the body 102y of the carrier-interposer 102 may (e.g., initially) be a unitary structure or a unitary piece of a material (or a combination of materials) that is processed (e.g., by way of etching or the like) to remove portion(s) thereof to define the cavity 102c. In other embodiments, multiple layers or sections of material (or a combination of materials) may be combined, such as overlaid on one another and adjoined and/or juxtaposed to one another and adjoined to form the body 102y, such that the cavity 102c naturally results due to the adjoining of the different layers or sections. In these embodiments, some or all of the vias 102v and/or some or all of the vias 102w may be formed in one or more of the multiple layers or sections of material(s).

In one or more embodiments, the PIC 106 may be positioned in the cavity 102c of the carrier-interposer 102 by aligning the PIC 106 with the cavity 102c, and lowering the PIC 106 such that the electrical contact pads 106d of the PIC 106 are coplanar with the electrical contact pads 102d of the carrier-interposer 102. The PIC 106 may be adhered (e.g., via an adhesive bond or layer 102a, such as glue, low temperature solder, and/or other types of adhesives) to the cavity 102c. See, e.g., view 100b of FIG. 1C. In certain embodiments, the PIC 106 may be fixed or snapped in place using ultraviolet (UV)-heat curing epoxy.

In exemplary embodiments, the dimensions of the cavity 102c may be defined such that, when the PIC 106 is positioned in the cavity 102c, there is a nominal by-design gap 102q between respective edges 106f of the PIC 106 and corresponding walls 102f of the cavity 102c for in-plane XY alignment of the patterns of electrical contact pads 106i of the PIC 106 and the bonding pad array 102b of the carrier-interposer 102. For instance, when the PIC 106 is aligned in the cavity 102c, the electrical contact pads 106i (which may be in a flip-chip pad pattern) and the bonding pad array 102b may be aligned as shown in view 100b of FIGS. 1C and 1n FIG. 1G. In one or more embodiments, such alignment may be achieved using computer vision pattern recognition of fiducials. As an example, the PIC 106 may be passively and precisely bonded to the cavity 102c in the XY-plane using computer vision recognition of fiducials with accuracy or precision that is finer than 1 micrometer (μm). In certain embodiments, this pattern alignment (or reconstructed pattern) may guide coupling or attachment of electrical contacts 104d and 104i of the EIC 104 (see view 100b of FIG. 1C) during a flip-chip process such as mass reflow.

In various embodiments, the nominal by-design gap 102q may be insensitive to the PIC 106 and dicing/etching tolerances of the cavity 102c. In one or more embodiments, the width of the nominal by-design gap 102q may be larger than about 1 μm (e.g., no less than about 1 μm). In some embodiments, in consideration of carrier-interposer cavity dimension tolerances as well as PIC dicing tolerances, the nominal by-design gap 102q may be about 15 μm to about 20 μm, or possibly even larger. In certain embodiments, the width of the nominal by-design gap 102q may be selected based on the type of material that the carrier interposer 102 and/or the PIC 106 are composed of and/or may be selected based on tolerances associated with the type of material that the carrier interposer 102 and/or the PIC 106 are composed of.

In one or more embodiments, height alignment of the PIC 106 and the carrier-interposer 102 may be controlled by a smart pick-up tool that references both a top surface (of the top side 102t) of the carrier-interposer 102 and a top surface (of the top side 106t) of the PIC 106. For example, one or more techniques described in co-pending U.S. patent application Ser. No. 18/194,674 entitled “MANAGING COMPONENT PLACEMENT IN DEVICE ASSEMBLY” and filed on Apr. 3, 2023 (published as U.S. Patent Publication No. 2024/0326252 on Oct. 3, 2024), which is incorporated by reference herein in its entirety, may be employed to facilitate the aforementioned height alignment of the PIC 106.

As illustrated in FIGS. 1A to 1C, the EIC 104 may, when coupled to the portion 1020 of the carrier-interposer 102, such as by way of flip-chip attachment of its electrical contact(s) 104i to contact pad(s) 106i of the PIC 106 (which may be configured as flip-chip pads) and of its electrical contacts 104d to the bonding pad array 102b, be disposed adjacent to (or over or partially over) both the carrier-interposer 102 and the PIC 106. In various embodiments, a polyimide passivation layer 102x may be utilized to facilitate under bump metallization (UBM) for creating reliable connections between the electrical contact(s) 104i and the contact pad(s) 106i of the PIC 106 and/or between the electrical contacts 104d and the bonding pad array 102b of the carrier-interposer 102. The UBM process may involve the depositing of metal layers on the contact pad(s) 106i of the PIC 106 and/or the bonding pad array 102b of the carrier-interposer 102. In some instances, a solder cap may also be applied over the UBM.

After the EIC 104 is installed, the vias 102w of the carrier-interposer 102 may facilitate electrical connectivity between the bonding pad array 102b and contacts on the bottom side 102m of the carrier-interposer 102. Furthermore, the EIC 104 may bridge the gap 102q between the carrier-interposer 102 and the PIC 106. An underfill 102u may be used to fill any spacing that might remain between the EIC 104 and the carrier-interposer 102 and/or the PIC 106 after flip-chip attachment, which can provide mechanical support and enhance the reliability of the interconnections by distributing the stress caused by thermal cycling and mechanical loads. The underfill 102u may be composed of any suitable material, such as, for instance, epoxy resin, silicone-based compounds, acrylate-based compounds, and/or the like.

With the EIC 104 installed, the entire assembly 100 may be coupled to a host substrate. Although not shown, the assembly 100, and more particularly pillars or solder bumps 102z on the bottom side 102m of the carrier-interposer 102, may be coupled to (e.g., disposed over) the substrate, and electrically coupled therewith. The substrate may be an organic substrate, such as a multi-layer laminate/printed circuit board (PCB) or a substrate-like PCB (SLP). Optical media, such as ferrules, a fiber array, or the like, may also then be coupled to the PIC 106. For instance, the cavity 102c of the carrier-interposer 102 may be defined with an opening 102g (see FIG. 1A) for butt-coupling of ferrules or a fiber array to the PIC 106 by way of optical interconnect(s) 106p.

In one or more embodiments, the vias 102v (e.g., FIGS. 1A, 1B) and/or the vias 102w (e.g., FIG. 1C) may be defined with select aspect ratios, and may be arranged or laid out with respect to one another in accordance with particular layout requirements, some or all of which may influence or dictate the type of material(s) that the carrier-interposer 102 is composed of. A suitable material may have a low dielectric constant, be easily machinable, allow for tight via design rules, and so on. Examples of such a material include glass, high-density build-up (HDBU) substrate, ceramic, coreless SLP, polymer(s), epoxy (ies), and/or the like.

The carrier-interposer 102 may include one or more RDLs—e.g., a top side RDL (not shown) and/or a bottom side RDL 1021—that are configured to fan-in and/or fan-out DC and RF signals to the pillars/solder bumps 102z, the contact pads 102d, the bonding pad array 102b, and/or any wire bonding pads (e.g., for DC). The RDL(s) may be composed of an electrically conductive material, such as, for instance, copper.

It is to be understood and appreciated that the carrier-interposer structure can be constructed to support a single PIC and a single EIC (such as that shown in FIGS. 1A to 1F), or can alternatively be constructed to support two or more PICS and/or two or more EICs. For instance, FIG. 1H shows an example assembly 100′ in which a carrier-interposer 102′ is configured to host a single PIC 106 and multiple EICs 104a, 104b that bridge over the PIC 106. The carrier-interposer 102′ may be generally similar to the carrier-interposer 102 described above, but may include separate bonding pad arrays/sets of vias or an expanded bonding pad array/set of vias for accommodating the multiple EICs 104a, 104b. Of course, the carrier-interposer 102′ may be configured to support additional EICs as desired. As another example, FIG. 1I shows an example assembly 100″ in which a carrier-interposer 102″ is configured to host multiple PICs 106a, 106b and a single EIC 104 that bridges over the multiple PICs 106a, 106b. The carrier-interposer 102″ may be generally similar to the carrier-interposer 102 described above, but may include individual sets of contact pads, vias, etc. for the individual PICs 106a, 106b. As yet another example, FIG. 1J shows an example assembly 100′″ in which a carrier-interposer 102′″ is configured to host multiple PICs 106a, 106b and multiple EICs 104a, 104b that respectively bridge over corresponding ones of the PICs 106a, 106b. The carrier-interposer 102′″ may be generally similar to the carrier-interposer 102 described above, but may include separate bonding pad arrays/sets of vias or an expanded bonding pad array/set of vias for accommodating the multiple EICs 104a, 104b as well as individual sets of contact pads, vias, etc. for the individual PICs 106a, 106b.

Coefficient of thermal expansion (CTE) is a measure of how much a material expands or contracts with changes in temperature. In cases where the vertical CTE of the carrier-interposer 102 and the PIC 106 are highly dissimilar (e.g., 3 parts per million per degree Celsius (ppm/° C.) for the PIC 106 versus 17 ppm/° C. for the carrier-interposer 102), the relative movement due to temperature excursions can create excess stress in the assembly. This stress can lead to cracking of the solder joints or even delamination in the dielectric layers of the flip-chip EIC 104. Thus, in one or more embodiments, a CTE balancing shim may be positioned under the PIC 106 to reduce this mismatch. For instance, in a case where the PIC 106 has a CTE of 3 ppm/° C. and the carrier-interposer 102 has a CTE of 17 ppm/° C., a shim that is composed of magnesium alloy (having a CTE of 26 ppm/° C.) and having the same height as the PIC 106 can balance the expansion of both sides of the stack-up, thereby mitigating the stress that is caused by thermal expansion differences. FIG. 1K shows a cross-sectional side view 100c of an example version of the assembly 100 of FIG. 1A (e.g., taken along line j in FIG. 1B) including an additional balancing shim 102k and an additional adhesive layer/bond 102j in the cavity 102c of the carrier-interposer 102.

In an example scenario where the PIC 106, the adhesive bond 102a, and the carrier-interposer 102 are not matched in CTE, the sums of the products of coefficient of thermal expansion (a) and height (h) can be balanced as follows:

$$( {α}_{PIC} \cdot {h}_{PIC} ) + ( {α}_{Adhesive 1} \cdot {h}_{Adhesive 1} ) = ( {α}_{C a r r i e r} \cdot {h}_{C a r r i e r} )$$

If it is not possible to balance this equation, an additional layer of shim and adhesive can be inserted, resulting in the following adjusted equation:

$$( {α}_{P1C} \cdot {h}_{PIC} ) + ( {α}_{Adhesive 1} \cdot {h}_{A dhesive 1} ) + ( {α}_{S h i m} \cdot {h}_{S h i m} ) + ( {α}_{Adhesive 2} \cdot {h}_{Adhesive 2} ) = ( {α}_{C a r r i e r} \cdot {h}_{C a r r i e r} )$$

All constants, except for the PIC height, the shim height, and the carrier-interposer depth can be tuned or modified to balance out this adjusted equation.

Example CTE mismatch calculations for various scenarios:
No balancing shim, low CTE carrier (e.g., glass)

| | | Height | | Δh @ 250° |
|---|---|---|---|---|
| | CTE | (μm) | 10⁻⁶ μm/° C. | C. (μm) |
| PIC | 3 | 400 | 1200 | −0.2 |
| Adhesive 1 | 16 | 40 | 640 | |
| Balancing shim | 0 | 0 | 0 | |
| Adhesive 2 | 0 | 0 | 0 | |
| Sum “PIC” side = | | | 1840 | |
| Carrier- | 6 | 440 | 2640 | |
| interposer | | | | |

No balancing shim, high CTE carrier (e.g., SLP)

| | | Height | | Δh @ 250° |
|---|---|---|---|---|
| | CTE | (μm) | 10⁻⁶ μm/° C. | C. (μm) |
| PIC | 3 | 400 | 1200 | −1.4 |
| Adhesive 1 | 16 | 40 | 640 | (danger, |
| Balancing shim | 0 | 0 | 0 | poor!) |
| Adhesive 2 | 0 | 0 | 0 | |
| Sum “PIC” side = | | | 1840 | |
| Carrier- | 17 | 440 | 7480 | |
| interposer | | | | |

Tuned balancing shim (e.g., magnesium alloy), high CTE carrier (e.g., SLP)

| | | Height | | Δh @ 250° |
|---|---|---|---|---|
| | CTE | (μm) | 10⁻⁶ μm/° C. | C. (μm) |
| PIC | 3 | 200 | 600 | −0.1 |
| Adhesive 1 | 16 | 40 | 640 | |
| Balancing shim | 26 | 200 | 5200 | |
| Adhesive 2 | 80 | 10 | 800 | |
| Sum “PIC” side = | | | 7240 | |
| Carrier- | 17 | 450 | 7650 | |
| interposer | | | | |

It will be understood and appreciated that, while embodiments have been described above as involving a PIC and an EIC, the carrier-interposer can be utilized to facilitate bridging of other chip combinations. For instance, the carrier-interposer may be utilized (or adapted) to facilitate bridging of the same type of chip, such as one or more EICs over one or more other EICs.

FIG. 1L is a perspective view of an example assembly 150 in which a (e.g., composite) carrier-interposer 152, including a first stage interposer 152a and a second stage interposer 152b, facilitates bridging of the EIC 104 over the PIC 106. FIG. 1M shows a side view 150a and a cross-sectional side view 150b of the assembly 150 of FIG. 1L (e.g., taken along line m or a line parallel thereto in FIG. 1L). The first stage interposer 152a may be similar to the carrier-interposer 102 of FIG. 1A in that it may include a body 152y having a portion 1520 and a portion 152p, but it may not include a cavity per se. Rather, a cavity/recessed surface 152r may result by virtue of the combination of the first and second stage interposers 152a and 152b—i.e., with the second stage interposer 152b being positioned over the portion 1520 of the first stage interposer 152a. The PIC 106 may be positioned over or on the cavity/recessed surface 152r.

Similar to the carrier-interposer 102, the first stage interposer 152a, and more particularly the portion 152p of the body 152y, may be defined with vias 152v (e.g., through carrier vias) that are respectively coupled to or defined in electrical contact pads 152d, for routing electrical signals from a top side (or surface) 152t of the first stage interposer 152a to a bottom side 152m of the first stage interposer 152a. The electrical contact pads 152d may be arranged to facilitate electrical connections 152e (e.g., wire bonding) with corresponding electrical contact pads 106d of the PIC 106.

The first and second stage interposers 152a and 152b may be composed of the same material or different materials. Example materials include glass, HDBU substrate, ceramic, coreless SLP, polymer(s), epoxy (ies), and/or the like. The first stage interposer 152a, and more particularly, the portion 1520 of the body 152y may be defined with vias 152w (e.g., through carrier vias) for routing electrical signals from the top side 152t of the first stage interposer 152a to a bottom side 152m of the first stage interposer 152a. The second stage interposer 152b may be defined with vias 153w (e.g., through carrier vias) for routing electrical signals from a top side 153t of the second stage interposer 152b to a bottom side 153m of the second stage interposer 152b. The vias 152w and 153w may be correspondingly coupled to one another by way of a connection pattern (or bump connections) 152j—e.g., copper pillars or hybrid bonds (such as chip-to-wafer hybrid bonding, which can provide for shorter interconnections). A bonding pad array 152k, similar to the bonding pad array 102b, may be arranged on the top side 153t of the second stage interposer 152b for facilitating electrical connections with corresponding electrical contacts of the EIC 104. See, e.g., view 150b of FIG. 1M.

The inclusion of vias 152v, 152w, and/or 153w in the composite carrier-interposer 152 advantageously reduces or eliminates a need for vias in the PIC 106 or the EIC 104, and thus no modifications to the structures of the PIC 106 and/or the EIC 104 may be needed.

In various embodiments, one or more aspects of the assembly 100 may similarly apply to the assembly 150. For instance, the assembly 150 may exhibit a nominal by-design gap 152q similar to the nominal by-design gap 102q (see view 150b of FIG. 1M). As another example, the assembly 150 may include one or more adhesive layers 162a similar to the adhesive layer 102a (see view 150b of FIG. 1M). As yet another example, UBM may be employed for creating reliable electrical connections. As a further example, the assembly 150 may include one or more balancing shims for at least partially balancing thermal expansion between the PIC 106 and the first stage interposer 152a. As an additional example, the assembly 150 may include an underfill 152u that fills any spacing that might remain between the EIC 104 and the second stage interposer 152b and/or the PIC 106 after flip-chip attachment (see view 150b of FIG. 1M). In one or more embodiments, that the composite carrier-interposer structure can be constructed to support two or more PICs and/or two or more EICs similar to that described above with respect to FIGS. 1H to 1J.

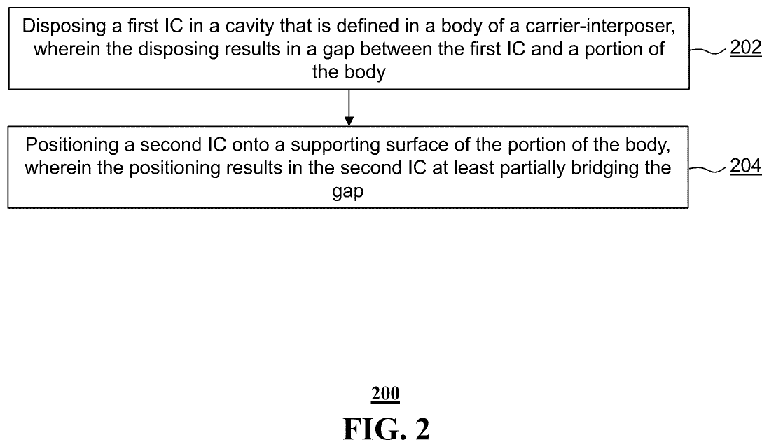

FIG. 2 depicts an illustrative embodiment of a method 200 in accordance with various aspects described herein.

At 202, the method may include disposing a first IC in a cavity that is defined in a body of a carrier-interposer, wherein the disposing results in a gap between the first IC and a portion of the body. For example, the method may include disposing the PIC 106 in the cavity 102c that is defined in the body 102y of the carrier-interposer 102, wherein the disposing results in the gap 102q between an edge 106f of the PIC 106 and a wall 102f of the portion 1020 of the body 102y. As another example, the method may include disposing the PIC 106 in cavity/recessed surface 152r that is defined in the overall body of the composite carrier-interposer 152 (i.e., the combination of the first and second stage interposers 152a and 152b), wherein the disposing results in the gap 152q between an edge of the PIC 106 and a portion of the overall body (i.e., the second stage interposer 152b).

At 204, the method may include positioning a second IC onto a supporting surface of the portion of the body, wherein the positioning results in the second IC at least partially bridging the gap. For example, the method may include positioning the EIC 104 onto a supporting surface of the portion 1020 of the body 102y, wherein the positioning results in the EIC 104 at least partially bridging the gap 102q. As another example, the method may include positioning the EIC 104 onto a supporting surface of the portion of the overall body of the composite carrier-interposer 152 (i.e., the second stage interposer 152b), wherein the positioning results in the EIC 104 at least partially bridging the gap 152q.

While for purposes of simplicity of explanation, the respective processes are shown and described as a series of blocks in FIG. 2, it is to be understood and appreciated that the claimed subject matter is not limited by the order of the blocks, as some blocks may occur in different orders and/or concurrently with other blocks from what is depicted and described herein. Moreover, not all illustrated blocks may be required to implement the methods described herein.

What has been described above includes mere examples of various embodiments. It is, of course, not possible to describe every conceivable combination of components or methodologies for purposes of describing these examples, but one of ordinary skill in the art can recognize that many further combinations and permutations of the present embodiments are possible. Accordingly, the embodiments disclosed and/or claimed herein are intended to embrace all such alterations, modifications and variations that fall within the spirit and scope of the appended claims. Furthermore, to the extent that the term “includes” is used in either the detailed description or the claims, such term is intended to be inclusive in a manner similar to the term “comprising” as “comprising” is interpreted when employed as a transitional word in a claim.

In addition, a flow diagram may include a “start” and/or “continue” indication. The “start” and “continue” indications reflect that the steps presented can optionally be incorporated in or otherwise used in conjunction with other routines. In this context, “start” indicates the beginning of the first step presented and may be preceded by other activities not specifically shown. Further, the “continue” indication reflects that the steps presented may be performed multiple times and/or may be succeeded by other activities not specifically shown. Further, while a flow diagram indicates a particular ordering of steps, other orderings are likewise possible provided that the principles of causality are maintained.

As may also be used herein, the term(s) “operably coupled to”, “coupled to”, and/or “coupling” includes direct coupling between items and/or indirect coupling between items via one or more intervening items. Such items and intervening items include, but are not limited to, junctions, communication paths, components, circuit elements, circuits, functional blocks, and/or devices. As an example of indirect coupling, a signal conveyed from a first item to a second item may be modified by one or more intervening items by modifying the form, nature or format of information in a signal, while one or more elements of the information in the signal are nevertheless conveyed in a manner than can be recognized by the second item. In a further example of indirect coupling, an action in a first item can cause a reaction on the second item, as a result of actions and/or reactions in one or more intervening items.

Although specific embodiments have been illustrated and described herein, it should be appreciated that any arrangement which achieves the same or similar purpose may be substituted for the embodiments described or shown by the subject disclosure. The subject disclosure is intended to cover any and all adaptations or variations of various embodiments. Combinations of the above embodiments, and other embodiments not specifically described herein, can be used in the subject disclosure. For instance, one or more features from one or more embodiments can be combined with one or more features of one or more other embodiments. In one or more embodiments, features that are positively recited can also be negatively recited and excluded from the embodiment with or without replacement by another structural and/or functional feature. The steps or functions described with respect to the embodiments of the subject disclosure can be performed in any order. The steps or functions described with respect to the embodiments of the subject disclosure can be performed alone or in combination with other steps or functions of the subject disclosure, as well as from other embodiments or from other steps that have not been described in the subject disclosure. Further, more than or less than all of the features described with respect to an embodiment can also be utilized. It is also to be understood and appreciated that the subject matter in one or more dependent claims may be combined with that in one or more other dependent claims.

What is claimed is:

1. A device, comprising:
a body having a cavity defined therein for hosting a first integrated circuit (IC), the body further having a portion adjacent to the cavity, the portion having a supporting surface for supporting and providing electrical interconnection to a second IC,
wherein the device facilitates bridging of the second IC at least partially over the first IC when the first IC is disposed in the cavity and the second IC is disposed over the supporting surface.

2. The device of claim 1, wherein the second IC at least partially bridges over a gap that is formed between a wall of the portion of the body and a wall of the first IC, when the first IC is disposed in the cavity.

3. The device of claim 1, wherein the portion is defined with one or more vias and includes a bonding pad array coupled to the one or more vias for interconnecting with one or more electrical contacts of the second IC when the second IC is disposed over the supporting surface.

4. The device of claim 1, wherein the body has another portion that is defined with one or more vias, and wherein the another portion includes one or more electrical contact pads coupled to the one or more vias for interconnecting with one or more electrical contacts of the first IC when the first IC is disposed in the cavity.

5. The device of claim 1, wherein the supporting surface is configured for flip chip attachment of the second IC.

6. The device of claim 1, wherein the first IC comprises a photonic IC (PIC), and wherein the second IC comprises an electronic IC (EIC).

7. The device of claim 1, wherein each of the first IC and the second IC comprises a respective electronic IC (EIC).

8. The device of claim 1, wherein the body is further defined with an opening for facilitating coupling of one or more components to the first IC.

9. The device of claim 8, wherein the first IC comprises one or more optical devices, and wherein the one or more components comprise one or more ferrules, one or more optical fibers, or a combination thereof.

10. The device of claim 1, wherein the body is composed of glass, a high-density build-up (HDBU) substrate, ceramic, a substrate-like printed circuit board (PCB) (SLP), one or more polymers, one or more epoxies, or a combination thereof.

11. The device of claim 1, wherein the body is a single unitary structure.

12. The device of claim 1, wherein the body is composed of multiple layers or sections that form the cavity when the multiple layers or sections are adjoined.

13. The device of claim 1, wherein a particular surface opposite the supporting surface is configured with one or more electrical contacts for coupling with one or more corresponding electrical contacts of a substrate.

14. An apparatus, comprising:
one or more first integrated circuits (ICs);
one or more second ICs; and
a carrier-interposer having a body that is defined with a cavity, the one or more first ICs being disposed in the cavity, the body further having a portion adjacent to the cavity, the portion having a supporting surface, and the one or more second ICs being disposed over the supporting surface,
wherein the one or more second ICs are bridged at least partially over the one or more first ICs and electrically interconnected to the one or more first ICs.

15. The apparatus of claim 14, further comprising one or more adhesive layers that are disposed in the cavity, the one or more adhesive layers coupling the one or more first ICs to the body of the carrier-interposer.

16. The apparatus of claim 14, further comprising one or more balancing shims that are disposed in the cavity, the one or more balancing shims being defined to at least partially balance thermal expansion between the one or more first ICs and the body of the carrier-interposer.

17. The apparatus of claim 14, wherein the one or more first ICs comprise one or more photonic ICs (PICs), and wherein the one or more second ICs comprise one or more electronic integrated circuit (EICs).

18. The apparatus of claim 14, wherein each of the one or more first ICs and each of the one or more second ICs comprise a respective electronic IC (EIC).

19. A method, comprising:
disposing a first integrated circuit (IC) in a cavity that is defined in a body of a carrier-interposer, wherein the disposing results in a gap between the first IC and a portion of the body; and
positioning a second IC onto a supporting surface of the portion of the body, wherein the positioning results in the second IC at least partially bridging the gap.

20. The method of claim 19, wherein the body comprises a first stage interposer that is disposed over the second stage interposer, and wherein the cavity is formed by virtue of the first stage interposer being disposed over the second stage interposer.
